(19) United States
(12) Patent Application Publication
(10) Pub. No.: US 2008/0237593 A1
(43) Pub. Date: Oct. 2, 2008

(54) Semiconductor Device, Method of Fabricating the Same, and Apparatus for Fabricating the Same

(76) Inventors: Junichiro Nakayama, Vancouver, WA (US); Ikumi Itsumi, Mie (JP); Tetsuya Inui, Nara (JP)

Correspondence Address: EDWARDS ANGELL PALMER & DODGE LLP, P.O. BOX 55874, BOSTON, MA, 02205, US

(21) Appl. No.: 11/794,874

(22) PCT Filed: Jan. 6, 2006
(86) PCT No.: PCT/JP06/00053

§ 371 Date: Nov. 29, 2007

(30) Foreign Application Priority Data
Jan. 7, 2005 (JP) 2005-002865

(51) Int. Cl. H01L 29/04; H01L 21/00; H01S 3/098

(52) U.S. Cl. 257/52; 438/795; 372/19; 257/E29.003; 257/E21.001

(57) ABSTRACT

There is provided a semiconductor device including a substrate and a semiconductor film deposited on the substrate, characterized in that the semiconductor film has a laterally grown crystal having an end with a surface projection height smaller than the thickness of the semiconductor film. There are also provided a semiconductor device fabrication method and apparatus utilizing a method and apparatus for fabricating the semiconductor device, that is capable of reducing a surface projection height or a ridge formed in a last region in repeating laser exposure in the SLS method, and a semiconductor device fabricated thereby.

### TECHNICAL FIELD

The present invention relates to a semiconductor device including an amorphous semiconductor material crystallized with a laser, a method of fabricating the same and an apparatus for fabricating the same.

### BACKGROUND ART

A thin film transistor (TFT) having a semiconductor device formed on a thin film of material is used in an active matrix liquid crystal display device for a display unit, a pixel controller and the like, and the thin film of material is formed mainly of amorphous material. Furthermore, to drive the TFT fast, it has its channel region, which has conventionally been formed of amorphous semiconductor film, crystallized to provide an improved material property. This is attributed to that a crystal, i.e., a portion having atoms arranged in alignment, allows a carrier to have a mobility several hundreds times larger than an amorphous portion would. However, a polycrystal has a grain boundary, which scatters a carrier. Accordingly, it is desirable to increase a crystal grain in size to provide a monocrystal in the channel region.

For crystallization, some methods have been proposed. A pulse laser can introduce large energy for a short period of time and accordingly allows a process to be performed at low temperature. As such, this approach has been developed. One such approach is a method referred to as lateral crystallization and sequential lateral solidification (SLS) utilizing lateral crystallization

A laterally grown crystal will be described with reference to FIGS. 8A and 8B. FIGS. 8A and 8B are front views of a film crystallized by lateral crystallization. More specifically, FIG. 8A shows a crystal grown using a mask having a small width and FIG. 8B shows a crystal grown using a mask having a large width. Lateral crystallization employs a mask and thus exposes an amorphous semiconductor film to a pulsed laser beam to completely melt this region. Subsequently, the semiconductor film is cooled and thus has its melted portion resolidified. At the time in a vicinity of a boundary with a solid portion that has not solidified there occurs unique, lateral crystallization with a crystal length L1. As shown in FIG. 8A, when a mask having a small width of some extent is used, such lateral crystals 71 and 72 collide with each other at a center of a pattern and provide a projecting surface roughness (hereinafter also referred to as a ridge). This is because when liquid silicon solidifies it increases in volume, and by the volume increased as it solidifies, an accordingly upward projection results. As shown in FIG. 8B, when a mask having a large width of some extent is used, then, while lateral crystallization proceeds, the film also starts to decrease in temperature in the vicinity of the center of the pattern and upward microcrystallization occurs. This will prevent lateral crystallization, and the lateral crystallization forms a ridge 73 and stops. Lateral crystal 71, 72 is a single, large monocrystal having a length extending from a completely melted end to ridge 73, and applying this direction to that of the channel of the TFT can provide a satisfactory characteristic as there does not exist a grain boundary perpendicular to a flow of a carrier.

The SLS method is a method for providing a further extended crystal length and, as shown in Japanese Patent National Publication No. 2000-505241 (hereinafter also referred to as Patent Document 1), this crystal can be used as a seed to continue lateral crystallization. A crystal formed by the SLS method will now be described with reference to FIGS. 9A-9D. FIGS. 9A-9D are front views of a film crystallized by the SLS method. Initially, as shown in FIG. 9A, a sample (an amorphous semiconductor film) is moved (or shifted) relative to a rectangular mask, a laser or the like by a distance L2, and thus exposed to laser light. A shifted, laser-exposed portion 83 completely melts and re-solidifies. In doing so, as shown in FIG. 9B, the immediately preceding crystal grain is taken over as a seed, and a large monocrystal having crystal length L2 plus a crystal length L3 can be obtained. Furthermore, as shown in FIGS. 9C and 9D, such shifting and laser exposure can be repeated to obtain a monocrystal of a length as desired.

In doing so, the sample can be shifted by an appropriate amount to eliminate an immediately preceding ridge formed in lateral crystallization. A region that covers a formed ridge is exposed to the subsequent laser light. The region again completely melts and accordingly, the ridge is eliminated and a new ridge results at a position advanced by lateral crystallization. Thus a last crystalline region provided with a TFT channel portion does not have a projecting surface roughness (or a surface projection height) referred to as a ridge, and can thus obtain a flat surface.

However, the SLS method also provides a ridge in a last region after laser exposure is repeated. This is a problem to a subsequent device fabrication process. For example, if a gate, a contact, other film and/or the like is/are deposited on the semiconductor film at a region including such ridge, then, not only does film thickness serve as a constraint but there is also a large possibility of an impaired characteristic, and furthermore, it will also be an obstacle to microfabrication in the future.

To reduce in height such ridge formed in a last region in the SLS method, Japanese Patent National Publication No. 2003-509845 (hereinafter also referred to as Patent Document 2) proposes laser beam intensity modulation employing an attenuator. The laser beam intensity modulation described in Patent Document 2 can melt a semiconductor film partially. As such, lateral crystallization does not occur and such ridge can be eliminated. This, however, requires an attenuator, a system driving the attenuator, and other additional equipment. Furthermore, when a high laser exposure frequency is used in a production system, such attenuators must be operated fast, and such system is difficult to implement.

Furthermore, Japanese Patent Laying-Open No. 2003-309080 (hereinafter also referred to as Patent Document 3) describes exposure to light having passed through a mask that is at most of a diffraction limit to reduce in height a ridge formed in a region crystallized by the SLS method. This technique exposes the entirety of the crystallized region to light and thus reduces the projection. The technique, however, provides a surface increased in unevenness and thus may have a risk of inviting an impaired characteristic of a TFT. Furthermore, the technique also requires that crystallization be limited in direction to a single direction.

### Patent Document 1: Japanese Patent National Publication No. 2000-505241

### Patent Document 2: Japanese Patent National Publication No. 2003-509845

### Patent Document 3: Japanese Patent Laying-Open No. 2003-309080

### DISCLOSURE OF THE INVENTION

### Problems to be Solved by the Invention

The present invention has been made to overcome the above described disadvantages and it contemplates a novel semiconductor device fabrication method and apparatus capable of reducing a surface projection height (or a ridge) of a last region that is provided after laser exposure is repeated in the SLS method, and a semiconductor device fabricated by the same.

### Means for Solving the Problems

The present semiconductor device has a basic structure including a substrate and a semiconductor film deposited on the substrate. The semiconductor film has a laterally grown crystal having an end with a surface projection height smaller than the thickness of the semiconductor film.

Herein preferably the laterally grown crystal is a crystal grown by subjecting the semiconductor film to laser exposure.

Furthermore, preferably the laterally grown crystal is a region having crystallization extended by taking over a crystal of a portion that has lateral crystallization provided by the laser exposure, as the laser exposure is shifted stepwise in the direction of the plane of the semiconductor film to take over the portion.

Furthermore in the present semiconductor device preferably the surface projection height located at the end of the laterally grown crystal is smaller than the thickness of the semiconductor film as light having passed through one of a slit and a pattern that are at most of a diffraction limit is utilized and the semiconductor film is thus exposed to laser light smaller in energy than that applied to provide the laterally grown crystal.

Furthermore, more preferably the present semiconductor device is fabricated by using the laser light smaller in energy than that applied to provide the laterally grown crystal, as described in any of the following items (1) to (3):

(1) it is used for a last exposure in exposing the semiconductor device to laser light stepwise;

(2) it is used from an exposure preceding a last exposure by a few steps through to the last exposure in exposing the semiconductor device to laser light stepwise; and

(3) it is used at a position of a last exposure in exposing the semiconductor device to laser light stepwise.

Furthermore the present invention provides a method of fabricating a semiconductor device, including the steps of: exposing a semiconductor film deposited on a substrate to laser light to provide a laterally grown crystal in the semiconductor film; and exposing the semiconductor film to laser light smaller in energy than that applied to provide the laterally grown crystal, to allow the laterally grown crystal to have an end with a surface projection height smaller than the thickness of the semiconductor film.

In the present method of fabricating the semiconductor device, preferably, exposing the semiconductor film to the laser light to provide the laterally grown crystal in the semiconductor film is shifted stepwise to take over a portion of the semiconductor film that has the grown crystal.

Preferably the present method of fabricating the semiconductor device also uses the laser light smaller in energy than that applied to provide the laterally grown crystal, as described in any of the following items (1) to (3):

(1) it is used for a last exposure in exposing to laser light shifted stepwise;

(2) it is used from an exposure preceding a last exposure by a few steps through to the last exposure in exposing to laser light shifted stepwise, and

(3) it is used at a position of a last exposure in exposing to laser light shifted stepwise.

Furthermore in the present method of fabricating the semiconductor device preferably a mask having one of a slit and a pattern that are at most of a diffraction limit is used to control energy in amount for exposure to expose the semiconductor film to the laser light smaller in energy than that applied to provide the laterally grown crystal.

Furthermore the present invention also provides a semiconductor device fabrication apparatus suitably used in the present method of fabricating the semiconductor device, as described above, including a first laser oscillator, a second laser oscillator, and a controller controlling the first and second laser oscillators.

In the present semiconductor device fabrication apparatus preferably the second laser oscillator generates laser light smaller in energy than that generated by the first laser oscillator.

Furthermore, more preferably the first laser oscillator generates laser light having a wavelength readily absorbable by a semiconductor film and the second laser oscillator generates laser light having a wavelength readily absorbable by one of a substrate and the semiconductor film melted.

Furthermore the present invention also provides a mask used in the method of fabricating the semiconductor device, that allows a semiconductor film deposited on a substrate to be exposed to laser light to provide a laterally grown crystal in the semiconductor film, and to laser light smaller in energy than that applied to provide the laterally grown crystal, to allow the laterally grown crystal to have an end with a surface projection height smaller than the thickness of the semiconductor film, the mask being used to provide the exposure to the laser light smaller in energy than that applied to provide the laterally grown crystal, the mask having one of a slit and a pattern that are at most of a diffraction limit.

Furthermore the present invention also provides a fabrication apparatus employed in the method of fabricating the semiconductor device, that allows a semiconductor film deposited on a substrate to be exposed to laser light to provide a laterally grown crystal in the semiconductor film, and to laser light smaller in energy than that applied to provide the laterally grown crystal, to allow the laterally grown crystal to have an end with a surface projection height smaller than the thickness of the semiconductor film, the apparatus including a mask used to provide the exposure to the laser light smaller in energy than that applied to provide the laterally grown crystal, the mask having one of a slit and a pattern that are at most of a diffraction limit.

### EFFECTS OF THE INVENTION

The present semiconductor device fabrication method, mask and semiconductor device fabrication apparatus is different than conventional as it does not require an attenuator, a system driving the attenuator or other similar equipment and also does not provide a surface increased in unevenness, and can thus provide a semiconductor device having a crystallized end with a surface projection height smaller than a semiconductor film's thickness. Such semiconductor device can provide an effectively better TFT characteristic than conventional. More specifically, it can effectively contribute to reducing threshold voltage, variation in threshold voltage, and subthreshold swing. Furthermore, in view of process, the absence of such projection at the end of crystallization also allows a gate oxide film to be reduced in thickness to be a thin film to provide a further improved throughput and a further improved TFT characteristic.

### BRIEF DESCRIPTION OF THE DRAWINGS

FIG. 1 is a schematic cross section of the present semiconductor device.

FIG. 2A is a plan view of a crystal of a semiconductor film in the present semiconductor device.

FIG. 2B is a cross section of the semiconductor film in the present semiconductor device.

FIG. 3A schematically shows a mask suitably used in the present semiconductor device fabrication method.

FIG. 3B schematically shows a mask suitably used in the present semiconductor device fabrication method.

FIG. 3C schematically shows a mask suitably used in the present semiconductor device fabrication method.

FIG. 3D schematically shows a mask suitably used in the present semiconductor device fabrication method.

FIG. 4A schematically shows a suitable laser light exposure method in the present semiconductor device fabrication method.

FIG. 4B schematically shows a suitable laser light exposure method in the present semiconductor device fabrication method.

FIG. 5 represents a concept of one example of an apparatus that can be used in the present semiconductor device fabrication method.

FIG. 6 represents a concept of a preferred example of the present semiconductor device fabrication apparatus.

FIG. 7 is a graph for generally illustrating a relationship between first laser light's exposure time and second laser light's exposure time and an output (or radiation illuminance) in the present semiconductor device fabrication apparatus.

FIG. 8A is a plan view of a film crystallized by lateral crystallization.

FIG. 8B is a plan view of the film crystallized by lateral crystallization.

FIG. 9A is a plan view of a film crystallized by the SLS method.

FIG. 9B is a plan view of the film crystallized by the SLS method.

FIG. 9C is a plan view of the film crystallized by the SLS method.

FIG. 9D is a plan view of the film crystallized by the SLS method.

FIG. 10 is a cross section of a semiconductor film in a conventional semiconductor device.

FIG. 11 schematically shows a conventional mask.

FIG. 12 schematically shows a conventional laser light exposure method.

### DESCRIPTION OF THE REFERENCE SIGNS

1: substrate, 2: underlying insulation film, 3: semiconductor film, 5: semiconductor device, 31, 32, 33, 34: mask, 41, 51: controller, 43, 53: variable attenuator, 44, 54: field lens, 45, 55: mask, 46, 56: imaging lens, 47, 57: sample stage, 42, 52: first laser oscillator, 58: second laser oscillator, 71, 81: crystal growth length, 82: distance, 83: laser-exposed portion

### BEST MODES FOR CARRYING OUT THE INVENTION

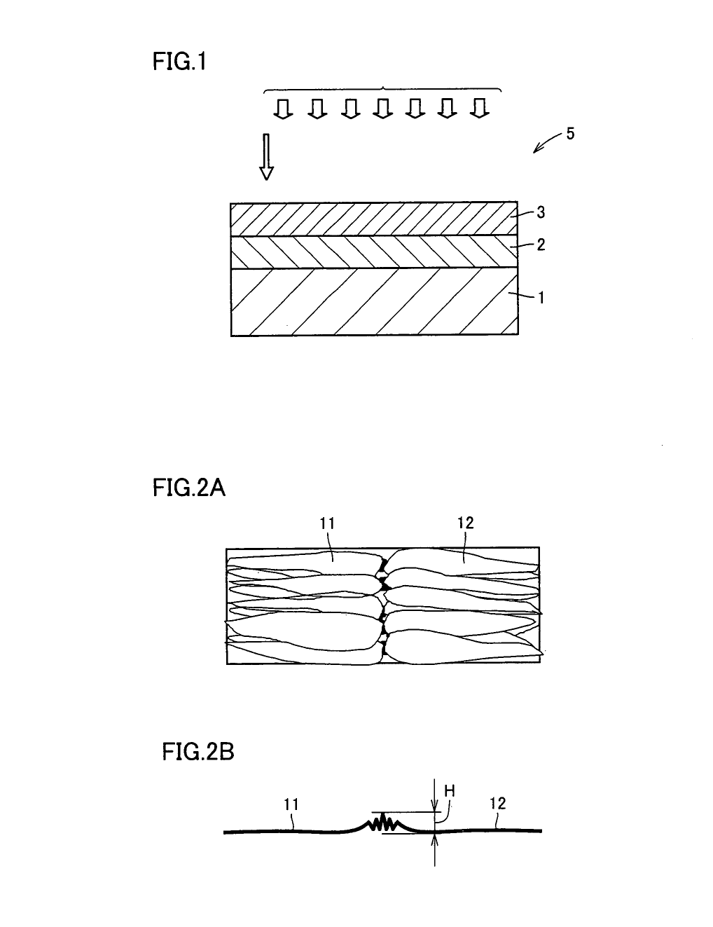

FIG. 1 is a schematic cross section of a semiconductor device 5 of the present invention. The present semiconductor device 5 has a basic structure including a substrate 1 and a semiconductor film 3 deposited substrate 1, preferably with an underlying insulation layer 2 posed between substrate 1 and semiconductor film 3, as shown in FIG. 1.

Preferably, the present semiconductor device 5 employs substrate 1 that is insulative. It can be a glass substrate, a quartz substrate or the like, and the glass substrate is suitably used as it is inexpensive and also allows such a substrate of a large area to be readily produced.

Underlying insulation film 2 can be formed of silicon oxide, silicon nitride or other similar material conventionally used in the art, and it can be deposited for example by the CVD method. However, it is not limited to such material or manner. In particular, silicon oxide is preferably used to form underlying insulation film 2, since silicon oxide is identical in component to a glass substrate and has a variety of physical properties, such as coefficient of thermal expansion, substantially equal thereto. Mainly when precursor semiconductor thin film is exposed to laser light and thus melted, and recrystallizes, underlying insulation film 2 can prevent a thermal effect of the melted, precursor semiconductor thin film from affecting an insulating substrate implemented for example as a glass substrate, and furthermore, prevent impurity diffusion from the insulating substrate implemented for example as the glass substrate to the precursor semiconductor thin film. Note that underlying insulation film 2 preferably has a thickness of approximately 50 to 200 nm. However, it is not limited thereto. Underlying insulation film 2 can be formed on substrate 1 by depositing the above material thereon by plasma enhanced chemical vapor deposition (PECVD), vapor deposition, sputtering or the like.

In the present semiconductor device 5, semiconductor film 3 is not limited to any particular film as long as it is a conventionally well known one exhibiting a semiconductive property. Preferably, amorphous silicon film is used to provide the semiconductor film, since amorphous silicon film has a variety of properties remarkably improved by providing an increased crystal growth length in lateral crystallization provided by laser exposure as described later. Semiconductor film 3 is, however, not limited to a semiconductor film formed of amorphous silicon or other similar amorphous material. It may also be a microcrystalline, polycrystalline or similarly crystalline semiconductor film. Furthermore, semiconductor film 3 is not limited in material to that formed of silicon alone. It may be formed of a material having a main component formed of silicon containing germanium or a similar element. Semiconductor film 3 can be deposited to have a thickness of 10 to 100 nm by plasma enhanced chemical vapor deposition (PECVD), catalytic chemical vapor deposition (Cat-CVD), vapor deposition, sputtering, or the like.

The present semiconductor device 5 includes semiconductor film 3 having a laterally grown crystal. “Lateral” as referred to herein indicates a direction substantially parallel to the plane of the semiconductor film. More specifically, for semiconductor film, a crystal is grown mainly in the direction of the plane of the film and that of the thickness of the film. Of the directions, the term “lateral” indicates the former direction.

The present semiconductor device 5 is characterized in that semiconductor film 3 has a laterally grown crystal having an end with a surface projection height smaller than the semiconductor film's thickness. Herein the surface projection height indicates a maximum height of a projection located at the end. It can be calculated by measuring a geometry of a surface of an area of 20 μm×20 μm with an atomic force microscope (AFM) and calculating an average value of at least five points largest in height. Furthermore, the semiconductor film's thickness indicates its average thickness. It can be calculated from a measurement, obtained through an atomic force microscope (AFM) or a contact-probe step height meter, of the height of a step provided between a region that has the semiconductor film and a region that does not have the semiconductor film. A semiconductor device including semiconductor film 3 having a laterally grown crystal having an end with a surface projection height smaller than the semiconductor film's thickness can provide an effectively better TFT characteristic than conventional. More specifically, it can effectively contribute to reducing threshold voltage, variation in threshold voltage, and subthreshold swing. Furthermore, in view of process, the absence of such projection at the end of crystallization also allows a gate oxide film to be reduced in thickness to be a thin film to provide a further improved throughput and a further improved TFT characteristic.

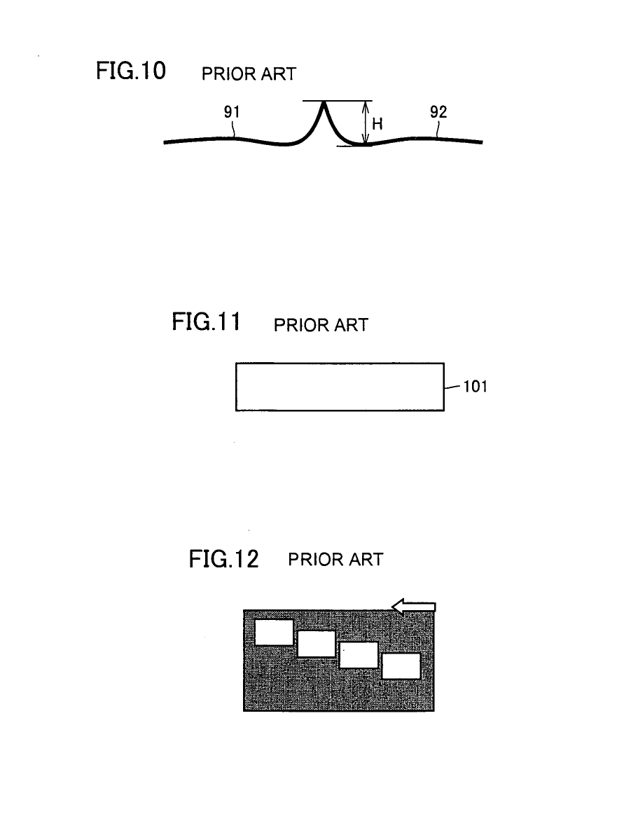

FIG. 2A is a plan view of a crystal of the semiconductor film in the present semiconductor device and FIG. 2B is a cross section of the semiconductor film in the present semiconductor device. Furthermore, FIG. 10 is a cross section of a semiconductor film in a semiconductor device as conventional. If the present semiconductor device has a semiconductor film having a thickness of 50 nm, for example, a laterally grown crystal 11, 12 has an end with a surface projection height H of 30 nm (FIG. 2B). In contrast, the conventional semiconductor device has a laterally grown crystal 91, 92 having an end with surface projection height H of 50 nm (FIG. 10). Thus in such example the present semiconductor device provides surface projection height H reduced from 50 nm as conventional to 30 nm and thus smaller than the semiconductor film's thickness. The surface projection height can further be reduced by employing a mask pattern to control energy in amount, and a crystal can be obtained that allows the area other than the ridge to be significantly flat and almost devoid of unevenness, more specifically, almost devoid of projection of equal to or larger than 10 nm.

The present semiconductor device is not limited to any particular device as long as the surface projection height is smaller than its semiconductor film's thickness. It is preferable, however, that there be a difference of at most 150 nm between the surface projection height and the semiconductor film's thickness, since the semiconductor film underlies a gate oxide film having a thickness of approximately 100 nm and if the projection breaks the gate oxide film a current leaks and the semiconductor device may not operate as a TFT. Furthermore, if the gate oxide film is not uniform in thickness, a varying threshold voltage is provided. Accordingly, the surface projection height should not be such a height that varies the gate oxide film in thickness. In this view, the difference between the surface projection light and the semiconductor film's thickness is more preferably at most 100 nm. Furthermore, as threshold voltage is inversely proportional to the gate oxide film's thickness, there is a tendency that the gate oxide film is reduced in thickness to be a thin film, and to do so, it is necessary to minimize the surface projection height. In this view, it is particularly preferable that the difference between the surface projection height and the semiconductor film's thickness be at most 50 nm.

Hereinafter will be described a method suitable for fabricating the present semiconductor device characterized as above (hereinafter also referred to as the present semiconductor device fabrication method). Note that the present semiconductor device may be any semiconductor device that is characterized as above. It is not limited to that fabricated in the present semiconductor device fabrication method.

The present semiconductor device fabrication method includes the steps of: exposing a semiconductor film deposited on a substrate to laser light to provide a laterally grown crystal in the semiconductor film; and exposing the semiconductor film to laser light smaller in energy than that applied to provide the laterally grown crystal, to allow the laterally grown crystal to have an end with a surface projection height smaller than the semiconductor film's thickness.

In the present semiconductor device fabrication method, at an initial step, a conventionally well known method referred to as SLS is employed to expose a semiconductor film deposited on a substrate to laser light to provide the semiconductor film with a laterally grown crystal. In a semiconductor film, a crystal is grown mainly in the direction of the plane of the film and that of the thickness of the film. The term “laterally” means the former direction, as has been described previously.

The step performed to provide such laterally grown crystal preferably includes shifting the laser exposure that provides the laterally grown crystal, stepwise to take over that portion of the semiconductor film which has the grown crystal. Herein, “laser exposure . . . stepwise” means exposing to a laser pulse to take over the lateral crystallization provided by a previous laser pulse, and exposing to a subsequent laser pulse to take over the crystallization provided by the laser pulse preceding that subsequent laser pulse. By such stepwise laser exposure, a crystal provided by an initial laser exposure can be taken over in morphology, and a single crystal, i.e., a monocrystal can be formed. Furthermore, a ridge resulting from an immediately preceding laser pulse exposure can also be removed by a subsequent laser pulse exposure. This can provide a crystal allowing the area other than a ridge to be significantly flat and almost devoid of unevenness, more specifically, almost devoid of projection of equal to or larger than 10 nm.

In the following step, laser light smaller in energy than that applied to provide the laterally grown crystal is provided to allow the laterally grown crystal to have an end with a surface projection height smaller than the semiconductor film's thickness. When crystallization laterally proceeds, a surface projection height results at an end portion corresponding to the end of the crystallization, as has been described previously. The present semiconductor device fabrication method is characterized in such surface projection height can be reduced to be smaller than the semiconductor film's thickness. More specifically, the present semiconductor device fabrication method provides low energy laser exposure, which cannot melt the semiconductor film completely, as seen depthwise, and instead melts the semiconductor film only partially at an upper portion. This provides crystal nuclei most of which are generated at a solid-liquid interface, and in the film, a microcrystal is grown from a lower portion toward a surface. Such recrystallization provided by a mechanism different than lateral crystallization allows the surface projection height to be sufficiently reduced. Furthermore, as will be described later, this is characterized in further utilizing an advantage of employing a laser having a large coefficient of absorption in the semiconductor film.

In this step, the exposure to the laser light smaller in energy than that applied to provide the laterally grown crystal is more preferably used, as indicated in any of the following items (1) to (3):

(1) It is used for a last exposure in exposing the semiconductor device to laser light stepwise;

(2) It is used from an exposure preceding a last exposure by a few steps through to the last exposure in exposing the semiconductor device to laser light stepwise; and

(3) It is used at the position of a last exposure in exposing the semiconductor device to laser light stepwise.

The exposure to the laser light smaller in energy than that applied to provide the laterally grown crystal, that is (1) used in a last exposure in exposing the semiconductor device to laser light stepwise, allows the last exposure for lateral crystallization to melt the film only partially at an upper portion to generate a large number of crystal nuclei at a solid-liquid interface and thus provide recrystallization in the film by a mechanism different than lateral crystallization to allow the surface projection height to be sufficiently reduced.

The exposure to the laser light smaller in energy than that applied to provide the laterally grown crystal, that is (2) used from an exposure preceding a last exposure by a few steps through to the last exposure in exposing the semiconductor device to laser light stepwise, can ensure that a surface projection height provided at an end of lateral crystallization is rendered smaller than the semiconductor film's thickness by designing to reduce laser energy gradually the few steps before if the laser energy in the last exposure is insufficiently small. Herein, the laser exposure preceding the last exposure by a few steps is preferably that preceding the last exposure by two to three steps. However, it is not limited thereto. It is preferable to provide an appropriate design to be able to achieve the goal of reducing a surface projection height to be smaller than the semiconductor film's thickness using a low energy laser together.

The exposure to the laser light smaller in energy than that applied to provide the laterally grown crystal, that is (3) used at the position of a last exposure in exposing the semiconductor device to laser light stepwise, can reduce a projection only at a ridge without affecting the other portions at all.

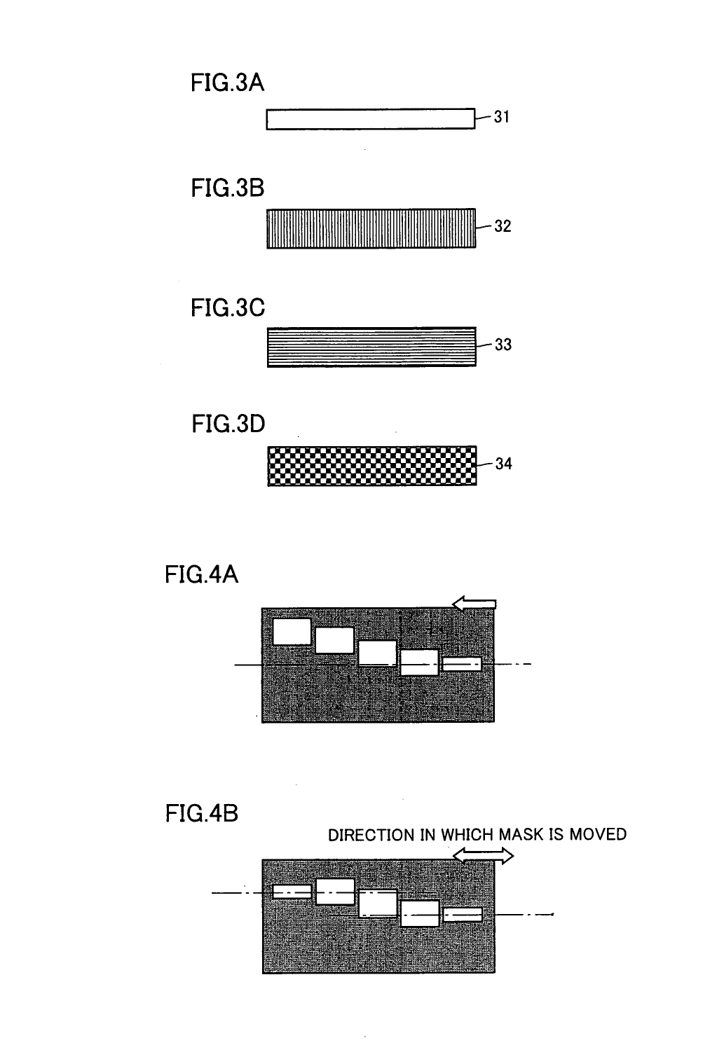

FIGS. 3A-3D schematically show masks suitably used in the present semiconductor device fabrication method. FIG. 11 schematically shows a conventional mask. The present semiconductor device is fabricated with exposure to laser light smaller in energy than that applied to provide lateral crystallization. Accordingly, a mask having a pattern 31 (FIG. 3A) narrower than a conventional slit pattern 101 (FIG. 11) or masks having slits or patterns 32 (FIG. 3B), 33 (FIG. 3C), 34 (FIG. 3D) that are at most of a diffraction limit is/are preferably used to control energy in amount for exposure. Such masks 31, 32, 33, 34 can be used to provide laser light that can reduce a ridge.

Pattern 31 narrower than conventional slit pattern 101 is similar in geometry to the conventional pattern and thus advantageous as it can be readily designed and produced. Patterns 32, 33, 34 that are at most of the diffraction limit can further reduce unevenness. Herein, the diffraction limit is determined by the wavelength of the excimer laser used and the optical system used. Generally, it is represented by λ/NA and will be approximately 1 to 3 μm. If an apparatus includes an excimer laser and an optical system that have a diffraction limit of approximately 3 μm, then a pattern that is at most of a diffraction limit will have a geometry of at most approximately 2 μm. A pattern that is at most of a diffraction limit transmits a reduced quantity of light, resulting in reduced energy. As such, if it is too small, it may have no effect. In this view, a size of ¼ to ¾ of the diffraction limit is suitable.

In the present invention, as a matter of course, a pattern narrower than a conventional slit pattern and a pattern that is at most of a diffraction limit can be combined together, as appropriate, to vary a projection in geometry, as desired. When the SLS method is employed to expose a semiconductor film to laser light to laterally grow a crystal, it crystallizes such that the direction in which the stage is shifted and that in which the crystal is laterally grown are substantially perpendicular to each other. In that case, a mask area having a slit or pattern that is at most of a limit of diffraction of light at a forward portion and a rearward portion will have a centerline on the same single line as that of the immediately preceding mask area.

Furthermore, if the semiconductor film is exposed to laser light with the stage reciprocated forward and backward, a mask having a slit or pattern that is at most of a limit of diffraction of light at a forward portion and a rearward portion is used (FIG. 4A) or a mask having a pattern narrower than a conventional slit pattern or a pattern that is at most of the diffraction limit is switched between traveling forward and traveling backward and thus used so that the pattern is set at the position of a last exposure (FIG. 4B). When the mask having a: pattern at the forward and rearward portions, as shown in FIG. 4A, is used, the semiconductor film is exposed to light passing through the mask that is at most of the diffraction limit before lateral crystallization, and effectively further reduced unevenness can be achieved. Note that FIG. 12 schematically shows an example of exposure to laser light, as conventional, as a comparison.

In the present invention, the semiconductor film is provided by a method employing laser light which is, desirably, large in coefficient of absorption in the semiconductor film to prevent the laser light from affecting the substrate. More specifically, the laser light preferably has a wavelength in the ultraviolet range. For example, it can be an excimer laser pulse having a wavelength of 308 nm. Note that in laser exposure for lateral crystallization if amorphous silicon having a thickness for example of approximately 50 nm is exposed to laser light to provide semiconductor film 3 having a laterally grown crystal, the SLS method requires an excimer laser to provide an amount of energy of 2 to 8 kJ/m². Furthermore, for the exposure to the laser light smaller in energy than that applied to provide lateral crystallization, the excimer laser provides an amount of energy of 0.5 to 4 kJ/m².

Furthermore, in the present invention, the semiconductor thin film is provided by the method that employs laser light which preferably has an amount of energy per the exposed area that melts the semiconductor film in solid state per one exposure, more specifically, an amount of energy that can heat the semiconductor film across its thickness to a temperature of at least its melting point. This amount of energy depends on the type(s) of the material(s) of the semiconductor film, the thickness of the semiconductor film, the area of the region to be crystallized, and the like, and cannot be determined uniquely. Accordingly, laser light having an appropriate amount of energy, as appropriate, is desirably used.

A general apparatus used to crystallize semiconductor films stacked in layers will now be described with reference to FIG. 5. FIG. 5 represents a concept of one example of an apparatus that can be employed in the present semiconductor device fabrication method as described above. The FIG. 5 exemplary apparatus includes a laser oscillator 42, a variable attenuator 43, a field lens 44, a mask 45, an imaging lens 46, a sample stage 47 and mirrors, and furthermore, an optical system allowing uniform exposure. These members are controlled by a controller 41. Such apparatus can supply a radiation pulse to semiconductor device 5 placed on stage 47. Furthermore, for laser light illuminating a ridge, a mask having a slit or pattern that is at most of a limit of diffraction of light can be used as mask 45 to attenuate laser energy. Such apparatus can be readily implemented by a skilled artisan appropriately combining various types of components of the art.

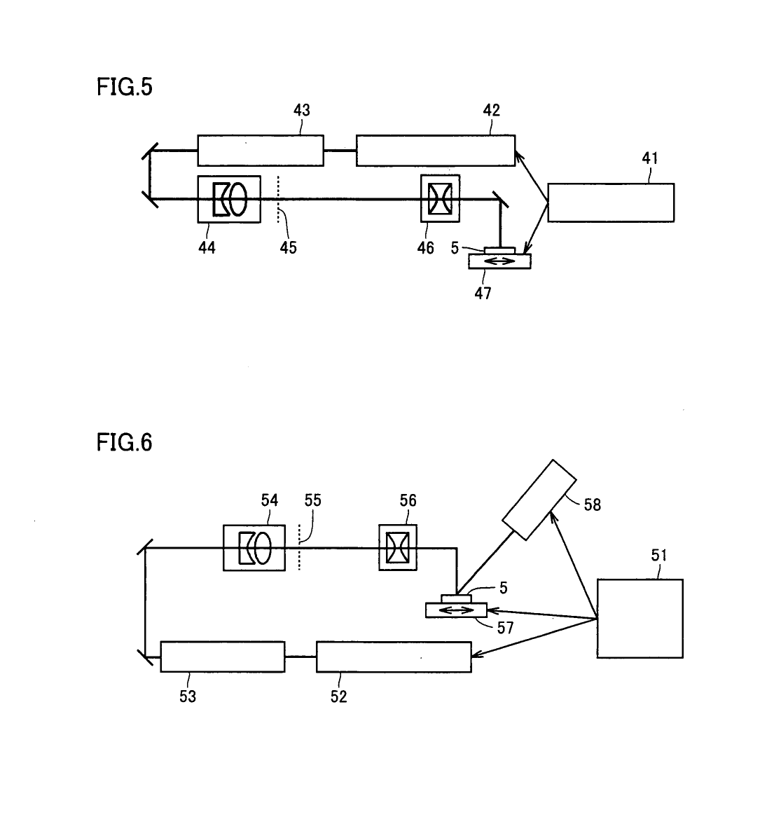

FIG. 6 shows a concept of a prepared example of the present semiconductor device fabrication apparatus. The present semiconductor device fabrication method can be implemented by employing such a general apparatus as shown in FIG. 5. In particular, the present semiconductor device fabrication apparatus as shown in FIG. 6 can suitably be used. The present invention also provides an apparatus suitably used in the above described, present semiconductor device fabrication method and characterized by including a first laser oscillator 52, a second laser oscillator 58 and a controller 51 controlling the two laser oscillators.

In the present semiconductor device fabrication apparatus shown in FIG. 6, the first laser oscillator 52 provides laser light used for exposure for the semiconductor film's lateral crystallization and the second laser oscillator 58 provides laser light used as assistive laser light to minimize or prevent reduction in temperature of the semiconductor film melted. Such arrangement can provide an extended period of time before the melted semiconductor film resolidifies, and a lateral crystal having a significantly increased grain size can be produced.

In the present semiconductor device fabrication apparatus preferably the first laser oscillator provides laser light (or first laser light) having a wavelength readily absorbable by the semiconductor film (in solid state) and the second laser oscillator provides laser light (or second laser light) having a wavelength readily absorbable by the substrate or the semiconductor film melted. Such first laser light for example includes an excimer laser pulse having a wavelength of 308 nm and such second laser light is provided by a YAG laser having a wavelength of 532 nm, a YAG laser having a wavelength of 1,064 nm, a carbonic acid gas laser having a wavelength of 10.6 μm.

In the present invention, the semiconductor film is produced by the apparatus employing the first laser light and the second laser light together preferably providing a total amount of energy that can melt the semiconductor film in solid state per one exposure per the area exposed. Alternatively, they can be set to have an amount of energy per the area exposed, such that the first laser light has an amount of energy that can melt the semiconductor film in solid state per one exposure per the area exposed and the second laser light is less than the amount of energy that can melt the semiconductor film in solid state per one exposure per the area exposed. These amounts of energy depend on the type(s) of the material(s) of the semiconductor film, the thickness of the semiconductor film, the area of the region to be crystallized, and the like, and cannot be determined uniquely. As such, it is desirable to adopt laser light having an appropriate amount of energy as appropriate in accordance with the manner to be applied in the present semiconductor device fabrication method as described above. For example, if the semiconductor film is amorphous silicon of 50 nm, the SLS method requires the first laser to provide an amount of energy of 1 to 5 kJ/m² and the second laser to provide an amount of energy of 0.5 to 4 kJ/m².

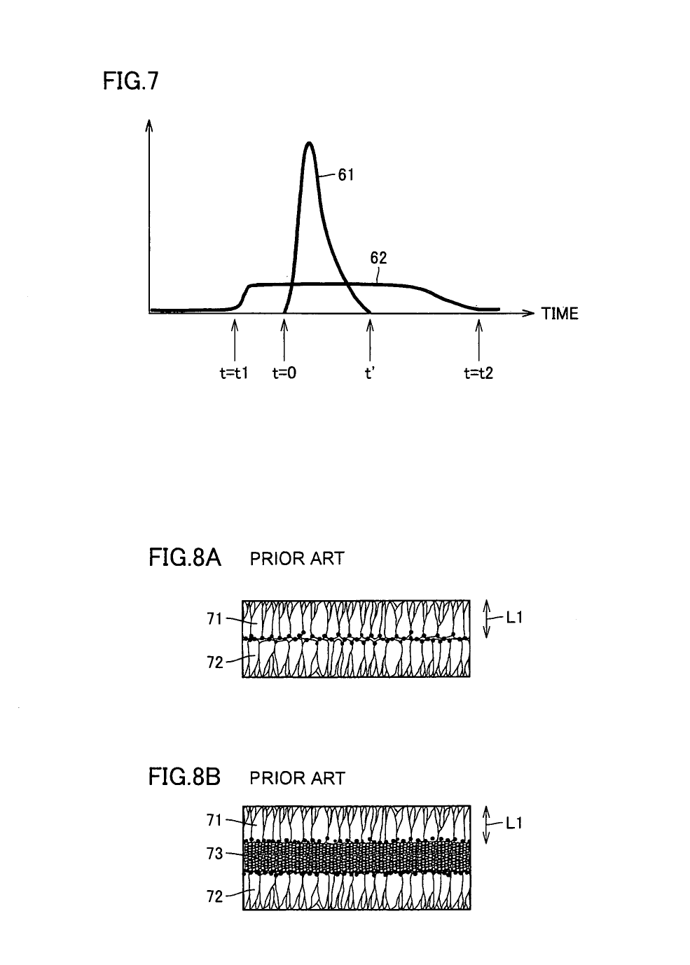

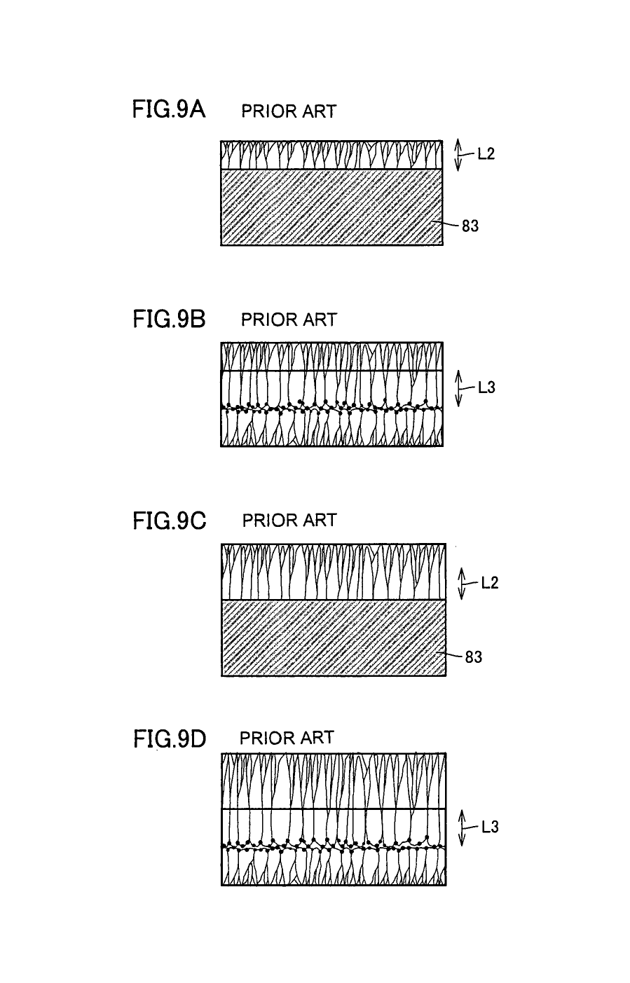

FIG. 7 is a graph for generally illustrating a relationship between the first laser light's exposure time and the second laser light's exposure time and an output (or radiation illuminance) in the present semiconductor device fabrication apparatus. In the FIG. 7 graph the horizontal axis represents time and the vertical axis represents the output in W/m². Furthermore in the FIG. 7 graph the first laser light is denoted by a reference character 61 and the second laser light is denoted by a reference character 62. The present semiconductor device fabrication apparatus is implemented for example to have the first laser provide exposure such that the first laser starts the exposure at a time t=0 and an output of 0 is provided at t=t′. Furthermore, the present semiconductor device fabrication apparatus is implemented for example such that the second laser radiates at a high output between time t1 and time t2 and at a low output for the time other than the period of time t1 to time t2. Note that t1<t2. The relationship between the first laser light's exposure time and the second laser light's exposure time and the output is not limited to such relationship as described above. Time t1 may have a positive value or a negative value. In other words, the second laser light's exposure may start at a time before or after the first laser light's exposure starts. Appropriately setting time t2 can provide an extended period of time before the melted semiconductor film resolidifies, and a lateral crystal having a significantly increased grain size can be produced. Preferably, t′<t2. Furthermore, t1<t′ is preferable. Such first laser light's exposure and second laser light's exposure are implemented as controlled, as appropriate, by controller 51. As controller 51, a conventionally known, appropriate control means can be used without a particular restriction.

Note that while FIGS. 3A-3D show masks suitably used in the present semiconductor device fabrication method, such masks are also novel and encompassed by the present invention. In other words, the present invention also provides a mask used in a semiconductor device fabrication method that allows a semiconductor film deposited on a substrate to be exposed to laser light to laterally grow a crystal in the semiconductor film, and to laser light smaller in energy than that applied to provide the laterally grown crystal, to allow the laterally grown crystal to have an end with a surface projection height smaller than a semiconductor film's thickness, the mask being used for exposing the semiconductor film to the laser light smaller in energy than that applied to provide the laterally grown crystal, the mask having a slit or pattern that is at most of a limit of diffraction.

Furthermore, the present invention also provides a fabrication apparatus including the above described mask. In other words, the present invention also provides a fabrication apparatus including a mask that is used in a semiconductor device fabrication method that allows a semiconductor film deposited on a substrate to be exposed to laser light to laterally grow a crystal in the semiconductor film, and to laser light smaller in energy than that applied to provide the laterally grown crystal, to allow the laterally grown crystal to have an end with a surface projection height smaller than a semiconductor film's thickness, the mask being used for exposing the semiconductor film to the laser light smaller in energy than that applied to provide the laterally grown crystal, the mask having a slit or pattern that is at most of a limit of diffraction.

It should be understood that the embodiments disclosed herein are illustrative and non-restrictive in any respect. The scope of the present invention is defined by the terms of the claims, rather than the description above, and is intended to include any modifications within the scope and meaning equivalent to the terms of the claims.

1-18. (canceled)

19. A semiconductor device comprising a substrate and a semiconductor film deposited on said substrate, said semiconductor film being exposed to laser light to have a laterally grown crystal, said laterally grown crystal having an end with a surface projection height smaller than a thickness of said semiconductor film by exposure to light passing through one of a silt and a pattern that are at most of a diffraction limit and disposed to be capable of exposing a projection formed at said end of said laterally grown crystal by said laser light applied to provide said laterally grown crystal, to laser light smaller in energy than that applied to provide said laterally grown crystal.

20. The semiconductor device according to claim 19, wherein said laterally grown crystal is a region having crystallization extended by taking over a crystal of a portion that has lateral crystallization provided by said laser exposure, as said laser exposure is shifted stepwise in a direction of a plane of said semiconductor film to take over said portion.

21. The semiconductor device according to claim 19, wherein said laser light smaller in energy than that applied to provide said laterally grown crystal is used for a last exposure in exposing the semiconductor device to laser light stepwise.

22. The semiconductor device according to claim 19, wherein said laser light smaller in energy than that applied to provide said laterally grown crystal is used from an exposure preceding a last exposure by a few steps through to said last exposure in exposing the semiconductor device to laser light stepwise.

23. The semiconductor device according to claim 19, wherein said laser light smaller in energy than that applied to provide said laterally grown crystal is used at a position of a last exposure in exposing the semiconductor device to laser light stepwise.

24. A method of fabricating the semiconductor device as recited in claim 19, comprising the steps of: exposing a semiconductor film deposited on a substrate to laser light to provide a laterally grown crystal in said semiconductor film; and exposing said semiconductor film to laser light smaller in energy than that applied to provide said laterally grown crystal, to allow said laterally grown crystal to have an end with a surface projection height smaller than a thickness of said semiconductor film.

25. The method of fabricating the semiconductor device according to claim 24, wherein said exposing said semiconductor film to said laser light to provide said laterally grown crystal in said semiconductor film is shifted stepwise to take over a portion of said semiconductor film that has said grown crystal.

26. The method of fabricating the semiconductor device according to claim 25, wherein said exposing said semiconductor film to said laser light smaller in energy than that applied to provide said laterally grown crystal is used for a last exposure in exposing to laser light shifted stepwise.

27. The method of fabricating the semiconductor device according to claim 25, wherein said exposing said semiconductor film to said laser light smaller in energy than that applied to provide said laterally grown crystal is used from an exposure preceding a last exposure by a few steps through to said last exposure in exposing to laser light shifted stepwise.

28. The method of fabricating the semiconductor device according to claim 25, wherein said exposing said semiconductor film to said laser light smaller in energy than that applied to provide said laterally grown crystal is used at a position of a last exposure in exposing to laser light shifted stepwise.

29. The method of fabricating the semiconductor device according to claim 24, wherein a mask having one of a slit and a pattern that are at most of a diffraction limit is used to control energy in amount for exposure to expose said semiconductor film to said laser light smaller in energy than that applied to provide said laterally grown crystal.

30. A semiconductor device fabrication apparatus used in the method of fabricating the semiconductor device, as recited in claim 24, comprising a first laser oscillator, a second laser oscillator, and a controller controlling said first and second laser oscillators.

31. The semiconductor device fabrication apparatus according to claim 30, wherein said second laser oscillator generates laser light smaller in energy than that generated by said first laser oscillator.

32. The semiconductor device fabrication apparatus according to claim 30, wherein said first laser oscillator generates laser light having a wavelength readily absorbable by a semiconductor film and said second laser oscillator generates laser light having a wavelength readily absorbable by one of a substrate and said semiconductor film melted.

33. A mask used in the method of fabricating the semiconductor device as recited in claim 24 to provide exposure to laser light smaller in energy than that applied to provide a laterally grown crystal, the mask having one of a slit and a pattern that are at most of a diffraction limit.

34. A fabrication apparatus employed in the method of fabricating the semiconductor device as recited in claim 24 to provide exposure to laser light smaller in energy than that applied to provide a laterally grown crystal, comprising a mask having one of a slit and a pattern that are at most of a diffraction limit.
